(19) United States
(12) Patent Application Publication
(10) Pub. No.: US 2007/0182485 A1
(43) Pub. Date: Aug. 9, 2007

(54) Predistorter for Linearization of Power Amplifier

(76) Inventor: Sang-Won Ko, Gainesville, FL (US)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/621,364

(22) Filed: Jan. 9, 2007

(30) Foreign Application Priority Data
Feb. 3, 2006 (KR) 10-2006-0010586

(51) Int. Cl. H03F 1/26

(52) U.S. Cl. 330/149

(57) ABSTRACT

A predistorter for the linearization of a power amplifier is provided. The predistorter can incorporate a field effect transistor (FET), which permits a design having low power consumption and broad band characteristics. The predistorter can be appropriate for integration with the power amplifier, unlike the conventional predistorters, because the subject predistorter does not significantly increase the size and complexity of the wireless system. In an embodiment, the subject predistorter can be coupled with a gate bias circuit of a power amplifier. When the predistorter is coupled with the gate bias of a power amplifier, the predistorter can function as linearizer as well as an adaptive gate bias circuit.

This application claims the benefit under 35 U.S.C. §119(e) of Korean Patent Application No. 10-2006-0010586 filed Feb. 3, 2006, which is incorporated herein by reference in its entirety.

### FIELD OF THE INVENTION

The subject invention pertains to a predistorter circuit for the linearization of a power amplifier.

### BACKGROUND OF THE INVENTION

In a wireless communication system, a power amplifier amplifies the input signal and delivers a sufficiently large signal to an antenna.

Ideally, the power amplifier amplifies the input signal linearly without distortion. However, the power amplifier is designed considering the power efficiency and thus the power amplifier necessarily causes the distortion of the signal in the process of signal amplification. Radio frequency (RF) modulation schemes in mobile wireless systems have a low tolerance for system non-linearity. Therefore, linearization techniques are used to improve the linearity performance of RF power amplifiers. Several linearization circuits were developed to prevent or compensate the distortion. These circuits include feedforward, feedback, and predistortion.

Predistorters include: an analog circuit commonly called a cuber or a cubic predistorter, which involves a system loop, delay lines, and a power splitter/coupler; an intermediate frequency (IF) predistorter, which can be analog or digital; and a digital circuit called a baseband predistorter, which involves a digital signal processor (DSP) and a lookup table.

A predistorter functions to inversely model a power amplifier's gain and phase characteristics for canceling non-linearity of the power amplifier. FIG. 1 shows a block diagram of a predistorter and a power amplifier.

Here, A1 is the input port of the predistorter (A2) and A2 is the predistorter. A3 is the output port of the predistorter (A2) and at the same time is the input port of the power amplifier (A4). A5 is the output port of the power amplifier. The predistorter (A4) is located in front of the power amplifier and compensates the distortion by the power amplifier.

FIG. 2 shows the general gain and phase relationship of the predistorter. As illustrated in FIG. 2, the gain of the predistorter increases with increasing input power, and the phase of the predistorter decreases with increasing input power. FIG. 3 shows the general gain and phase relationship of the power amplifier. As illustrated in FIG. 3, the gain of the power amplifier decreases with increasing input power, and the phase of the power amplifier increases with increasing input power.

Accordingly, when the predistorter is connected in series with the power amplifier, the distortion of the power amplifier is compensated by the predistorter. In practice, “increase of the gain of the predistorter” means “decrease of the loss of the predistorter” with increasing input power.

### BRIEF SUMMARY

The subject invention pertains to a predistorter for the linearization of a power amplifier. An object of an embodiment of the subject invention is to provide a predistorter which is simple and can be integrated with the gate bias circuit of a power amplifier.

When the predistorter is integrated with the gate bias circuit of the power amplifier, the predistorter can function as a linearizer as well as an adaptive gate bias circuit.

In embodiments, the predistorter does not require many passive elements and, thus, the size of the circuit can be small and can be suitable for integration. In addition, the predistorter can have a broad-band characteristic and low power consumption.

### BRIEF DESCRIPTION OF THE DRAWINGS

FIG. 1 shows a block diagram of a predistorter and a power amplifier.

FIG. 2 shows the gain and phase of a predistorter versus input power.

FIG. 3 shows the gain and phase of a power amplifier versus input power.

FIG. 4 shows a FET biased near “cold FET” condition.

FIG. 5 shows the reflection scattering parameter S(1,1) seen from the input port (B1) of FIG. 4 from 1 MHz to 20 GHz.

FIG. 6 shows the resistance of FET (B3) at 1 GHz when the gate of the FET (B3) of FIG. 4 is biased at −0.5 volt.

FIG. 7 shows a predistorter for the linearization of a power amplifier according to an embodiment of the subject invention.

FIG. 8 shows the ac voltage at node (C2) of FIG. 7 in the time domain when the input power is applied at input port (C1).

FIG. 9 shows the variation of dc voltage at node (C2) of FIG. 7 when a 1 GHz signal is applied at the input port (C1).

FIG. 10 shows the ac voltage at node (C2) of FIG. 7 divided by ac current flowing from the input port (C1) to the node (C2).

FIG. 11 shows the transmission scattering parameter S(2,1) of FIG. 7 when a 1 GHz signal is applied at the input port (C1).

FIG. 12 shows a predistorter coupled with the gate bias circuit of a power amplifier according to an embodiment of the subject invention.

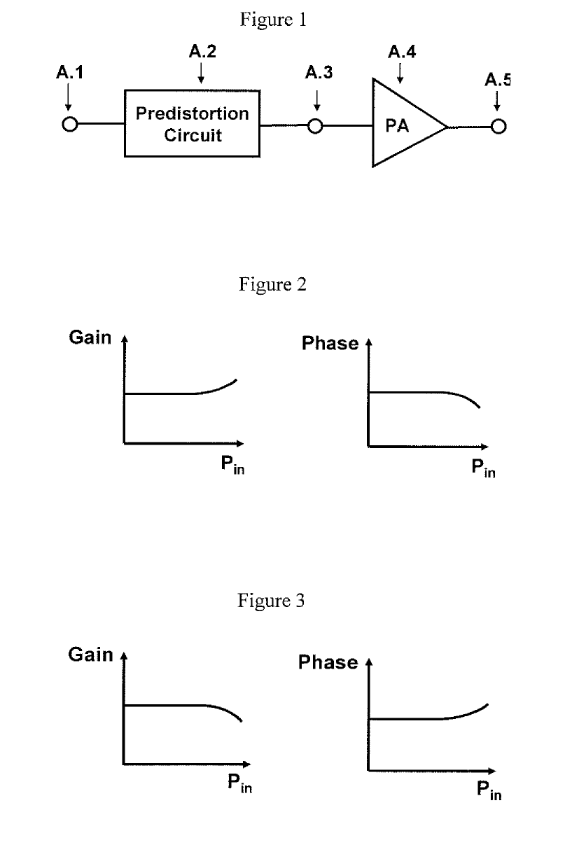

### REFERENCE CHARACTERS

A.1, B.1, C.1, and D.1: Input port

A.3, B.2, C.2, and D.2: Node

Cb: Capacitor

A.5, C.3, and D.3: Output port

B.3, C.4, and D.5: FET of a predistorter

D.4: FET of a power amplifier

### DETAILED DESCRIPTION OF THE INVENTION

FIG. 7 illustrates a basic circuit configuration of a predistorter according to an embodiment of the present invention. The basic configuration of the predistorter can include a FET and dc blocking capacitors. As shown in FIG. 7, the drain (or source) of the FET can be grounded and the source (or drain) of the FET can be connected to a node which is connected to dc blocking capacitors. The gate of the FET can be biased by a voltage (Vg).

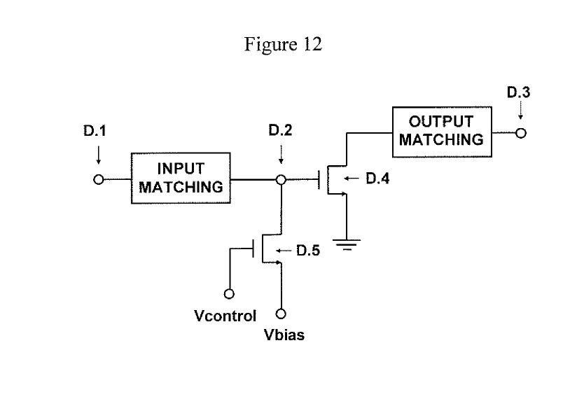

In a preferred embodiment, the predistorter can be coupled with a gate bias circuit of a power amplifier as shown in FIG. 12. Here, the drain (or source) of the predistorter can be biased by a voltage (Vbias), and this voltage can be applied to the gate (D2) of the power amplifier. The gate of the FET of the predistorter can be biased by another voltage (Vcontrol). The input matching network and output matching network can be located at the input and output of the circuit, respectively.

In various embodiments, a chip MESFET or a chip MOSFET can be used for the subject predistorter.

For a FET to function as a predistorter, the voltage from the drain to the source needs to be zero and the voltage at the gate of the FET should be bigger than the threshold voltage. Accordingly, the gate voltage needs to be selected appropriately.

The predistorter can be applicable for both MOSFET in a CMOS process or MESFET in a compound semiconductor process.

In a preferred embodiment, the subject predistorter can be a single FET. A MESFET or MOSFET can be used for the single FET of the predistorter. For a FET to be used, the parasitic capacitance from the package of FET needs to be small. Therefore, the appropriated devices for a predistorter are chip MESFET, chip MOSFET, monolithic MESFET of a compound semiconductor process, and monolithic MOSFET of a CMOS process. Meanwhile, for the FET to function as the predistorter, the FET should be biased in a particular operation condition. The drain to source voltage of the FET needs to be zero and the gate to source voltage of the FET should be bigger than the threshold voltage. In particular, the gate to source voltage should be a little less than the bias voltage for the “cold FET” condition.

When a FET is biased in the “cold FET” condition, the capacitance of the FET becomes very small.

While the conventional predistorter occupies a large circuit area and consumes large amounts of power, the subject predistorter can be incorporated with the gate bias circuit of a power amplifier.

Thus, the embodiments of the subject predistorter have a simple configuration and require only a small circuit area.

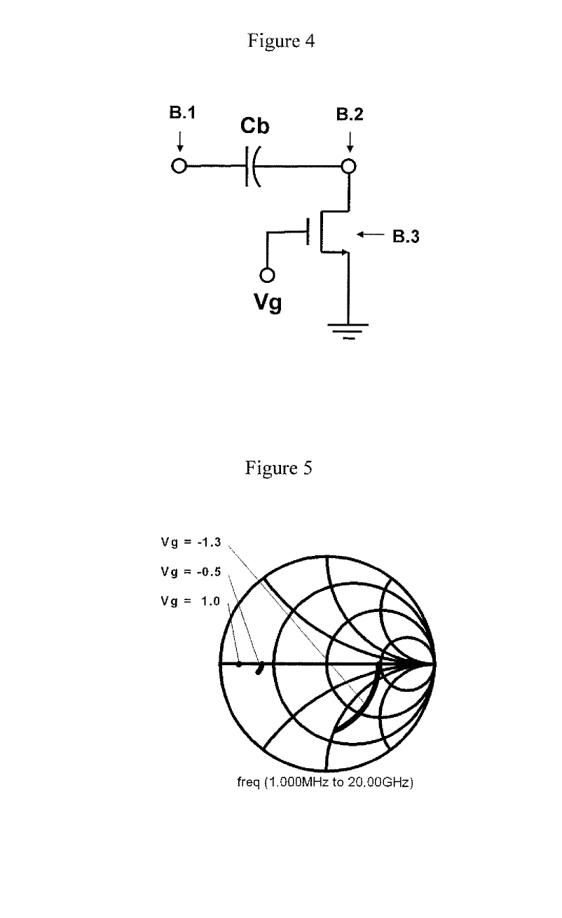

FIG. 4 shows a characteristic of a FET biased near the “cold FET” condition.

Referring to FIG. 4, B1 is the signal input port and the B3 is the FET used as the predistorter. Cb is a dc blocking capacitor and B2 is a node in which the dc blocking capacitor (Cb) and the FET (B3) are connected. In this embodiment, the drain of FET (B3) is not biased and thus the drain to source voltage is zero.

The reflection scattering parameter S(1,1) seen from the input port (B1) of FIG. 4 is shown from 1 MHz to 20 GHz in FIG. 5. Here, a chip MESFET is used for the simulation and the threshold voltage of the MESFET is −1.3 volt. If a MOSFET in a CMOS process is used for the design, the threshold voltage is positive voltage.

When a FET is biased in “cold FET” condition (the case of Vg=1 in FIG. 5), the resistance of FET become less than 10Ω. If the FET in “cold FET” condition is used for the predistorter, the loss through the predistorter is significant. Thus, the gate bias voltage for the FET of the predistorter should be a little less than the bias voltage for the “cold FET” condition.

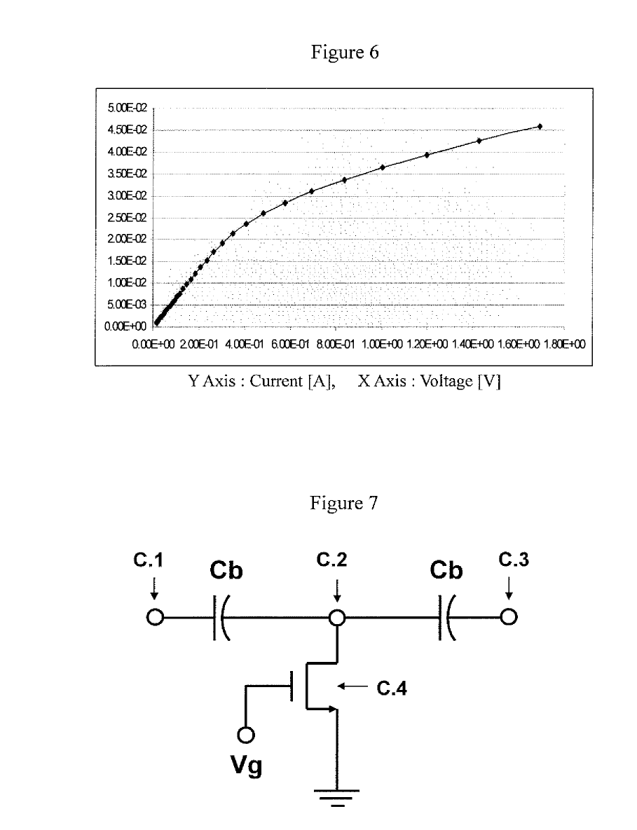

FIG. 6 shows a plot of current versus voltage for the predistorter of FIG. 4. The X axis of represents the ac voltage at node B2 and the Y axis represents the ac current flowing through the FET. The slope of the line represents the resistance of the FET when the ac signal is applied into the input port B1. An ac signal of 1 GHz is used for the simulation and the signal power is increased from −20 dBm to 16 dBm. As shown in FIG. 6, as the input power increases, the resistance of the FET increases.

FIG. 7 shows an embodiment of a predistorter for the linearization of a power amplifier.

Referring again to FIG. 7, the source of the FET (C4) can be grounded and the gate can be biased by Vg. C1 represents an input port and C3 represents an output port. C2 is the node in which the FET (C4) is connected to the signal path. Two capacitors (Cb) can be dc blocking capacitors, which are used to isolate the de voltage at node C2 from the input port and the output port.

In FIG. 7, when there is no input signal, the dc voltage at node C2 is zero volts. However, as the gate voltage (Vg) increase above the threshold voltage, the resistance of the FET decreases and the FET (C4) becomes appropriate for use as a predistorter.

Meanwhile, the gate width of the FET is another design parameter. As the gate width increases, the resistance of a FET decreases.

On the other hand, as the input power increases, the dc voltage at node C2 increases.

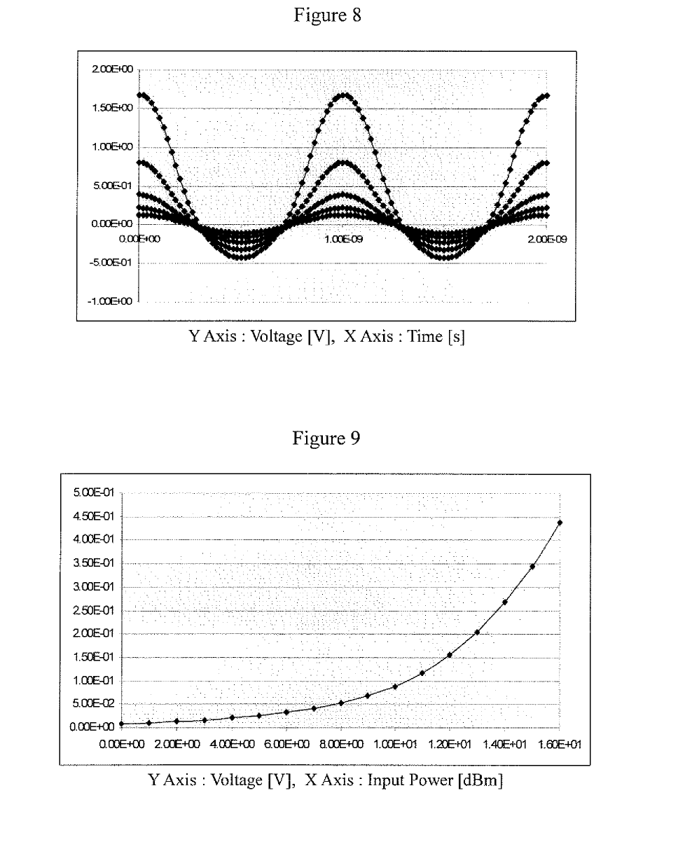

FIG. 8 shows the ac voltage versus time at node C2 of FIG. 7 when both the input port (C1) and the output port (C3) are terminated by 50Ω and the gate voltage (Vg) of the FET is −0.5 volt.

FIG. 8 illustrates the voltage waveform at node (C2) when input power is applied at the input port (C1). Each line in the plot indicates ac voltage for the input power of 0 dBm, 4 dBm, 8 dBm, 12 dBm, and 16 dBm, respectively. The frequency of the input signal is set to 1 GHz. As the input power increases, the voltage swing becomes bigger for the positive side than for the negative side. This is because the resistance of the FET increases as the ac voltage positively increases.

FIG. 9 shows the variation of dc voltage at node (C2) when both the input port (C1) and the output port (C3) are terminated with 50Ω resistance. The input power increases from 0 dBm to 16 dBm and the frequency of the input signal is 1 GHz. As the input power increases, the voltage swing becomes bigger for the positive side than for the negative side, and the positive dc voltage is generated from the even harmonic component of the ac voltage swing.

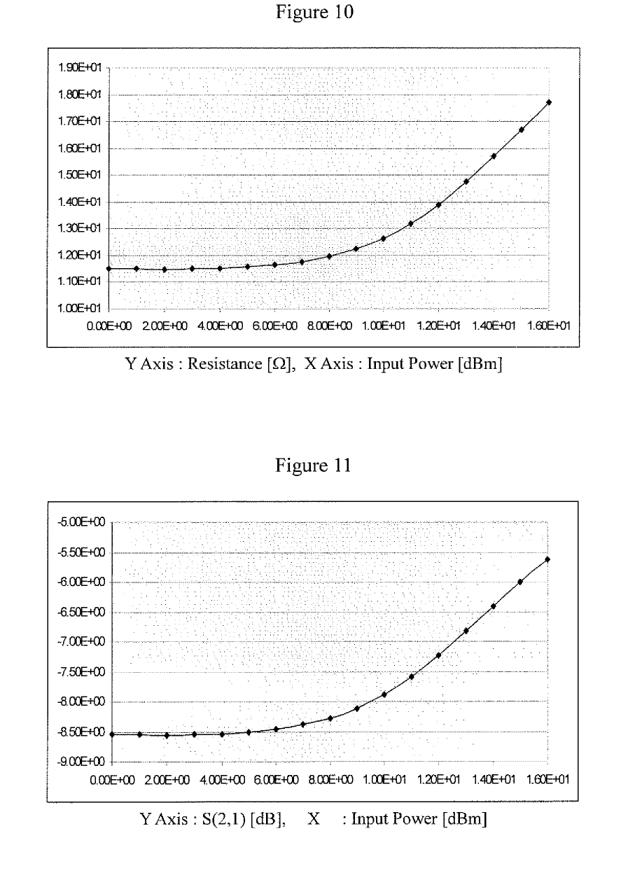

FIG. 10 shows the ac voltage at node (C2) divided by the ac current flowing from the input port (C1) to the node (C2), when both the input port (C1) and the output port (C3) are terminated with 50Ω resistance. This plot represents the resistance of the circuit of FIG. 7. As the input power increases, the resistance increases.

FIG. 11 shows the transmission scattering parameter S(2,1) when both the input port and the output port are terminated with 50Ω resistance and the gate voltage (Vg) is −0.5 volt. As the input power increases, the loss through the circuit of FIG. 7 decreases and S (2,1) increases. Therefore, it can be seen that the circuit of FIG. 7 functions as a predistorter.

The subject predistorter can be located in front of the power amplifier as a separate linearizer circuit like a conventional predistorter. In another embodiment, the subject predistorter can be coupled with the gate bias circuit of a power amplifier.

FIG. 12 shows a predistorter coupled with a gate bias circuit. D1 is the signal input port, D3 is the signal output port and D2 is the node in which the FET of the predistorter is connected. D4 is the FET of the power amplifier and D5 is the FET of the predistorter.

A voltage (Vbias) can be applied to the source of the FET (D4) and the drain to source voltage of FET (D4) can be zero. Thus the voltage (Vbias) is also applied at node D2 as a gate bias voltage for the power amplifier.

Another voltage (Vcontrol) can be applied to the gate of the FET (D5) of the predistorter and this voltage should be adjusted appropriately.

As the input power increases, the resistance of the FET (D5) of the predistorter increases.

Thus, as the input power increases, the loss of the FET (D5) decreases and the FET (D5) compensates the gain drop of the power amplifier.

Meanwhile, as the input power increases, the dc voltage at node (D2) increases and the predistorter can also function as an adaptive gate bias circuit. Therefore, the variation of the dc voltage at node (D2) should be considered when the predistorter is designed.

Accordingly, embodiments of the subject predistorter can be formed of a single FET and do not require many passive elements. Thus, the size of the predistorter can be small and has an appropriate configuration for integration. Furthermore, the subject predistorter can have broad-band characteristics and low power consumption. When the predistorter is coupled with a gate bias circuit of a power amplifier, the predistorter can also function as an adaptive gate bias circuit.

It should be understood that the examples and embodiments described herein are for illustrative purposes only and that various modifications or changes in light thereof will be suggested to persons skilled in the art and are to be included within the spirit and purview of this application.

I claim:

1. A predistorter for linearization of a power amplifier, comprising:
a first DC blocking capacitor connected in series between an input port and a signal path node;
a second DC blocking capacitor connected in series between the signal path node and an output port; and
a field effect transistor (FET) having a drain, a source, and a gate, wherein the drain (or source) of the FET connects to the signal path node, the source (or drain) of the FET is grounded, and the gate of the FET is biased by a gate voltage.

2. The predistorter according to claim 1, wherein the FET is a MESFET or a MOSFET.

3. The predistorter according to claim 1, wherein a voltage between the drain and the source of the FET is 0 V, and wherein the gate voltage of the FET is a little larger than a bias voltage for a cold FET condition.

4. A predistorter for linearization of a power amplifier, comprising:
a field effect transistor (FET) having a drain, a source, and a gate, wherein the drain (or source) of the FET connects to an input matching circuit and a gate of a transistor of a power amplifier, the source (or drain) of the FET is biased by a voltage for biasing the gate of the transistor of the power amplifier, and the gate of the FET is biased by a control voltage.

5. The predistorter according to claim 4, wherein the FET is a MESFET or a MOSFET.

6. The predistorter according to claim 4, wherein a voltage between the drain and the source of the FET is 0 V, and wherein the gate voltage of the FET is a little larger than a bias voltage for a cold FET condition.

7. The predistorter according to claim 4, wherein a drain (or source) of the transistor of the power amplifier is connected to an output matching circuit.
